(19) United States
(12) Patent Application Publication
(10) Pub. No.: US 2024/0047365 A1
(43) Pub. Date: Feb. 8, 2024

(54) STRUCTURE AND FORMATION METHOD OF PACKAGE WITH INTEGRATED CHIPS

(71) Applicant: Taiwan Semiconductor Manufacturing Company, Ltd., Hsinchu (TW)

(72) Inventors: Chuei-Tang WANG, Taichung City (TW); Tso-Jung CHANG, Taoyuan City (TW); Jeng-Shien HSIEH, Kaohsiung (TW); Shih-Ping LIN, Taichung City (TW); Chieh-Yen CHEN, Taipei City (TW); Chen-Hua YU, Hsinchu City (TW)

(73) Assignee: Taiwan Semiconductor Manufacturing Company, Ltd., Hsinchu (TW)

(21) Appl. No.: 18/150,539

(22) Filed: Jan. 5, 2023

Related U.S. Application Data
(60) Provisional application No. 63/395,226, filed on Aug. 4, 2022.

(51) Int. Cl. H01L 23/538; H01L 23/00; H01L 25/065; H01L 21/48

(52) U.S. Cl. CPC H01L 23/5386; H01L 24/13; H01L 24/08; H01L 24/80; H01L 25/0652; H01L 21/4857; H01L 21/486; H01L 23/5383; H01L 2224/13023; H01L 2224/08235; H01L 2224/08146; H01L 2224/80006; H01L 2224/80895; H01L 2224/80896; H01L 2924/182

(57) ABSTRACT

A package structure and a formation method are provided. The method includes disposing a first chip structure and a second chip structure over a carrier substrate. The method also includes forming an interconnection structure directly over and contacting the first chip structure and the second chip structure. The interconnection structure has multiple dielectric layers and multiple conductive features. One of the conductive features extends across a first edge of the first chip structure and a second edge of the second chip structure and is electrically connecting the first chip structure and the second chip structure. The method further includes directly bonding a third chip structure to the interconnection structure through dielectric-to-dielectric bonding and metal-to-metal bonding.

### PRIORITY CLAIM AND CROSS-REFERENCE

This Application claims the benefit of U.S. Provisional Application No. 63/395,226, filed on Aug. 4, 2022, the entirety of which is incorporated by reference herein.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature sizes (i.e., the smallest component that can be created using a fabrication process) have decreased. This scaling-down process generally provides benefits by increasing production efficiency and lowering associated costs.

A chip package not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor dies. These relatively new types of packaging technologies for semiconductor dies face manufacturing challenges.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1H are cross-sectional views of various stages of a process for forming a package structure, in accordance with some embodiments.

FIG. 1H-1 is a top view of an intermediate stage of a process for forming a package structure, in accordance with some embodiments.

FIG. 1H-2 is a cross-sectional view of an intermediate stage of a process for forming a package structure, in accordance with some embodiments.

FIGS. 2A-2H are cross-sectional views of various stages of a process for forming a package structure, in accordance with some embodiments.

FIGS. 3A-3H are cross-sectional views of various stages of a process for forming a package structure, in accordance with some embodiments.

FIGS. 4A-4F are cross-sectional views of various stages of a process for forming a package structure, in accordance with some embodiments.

FIG. 5 is a cross-sectional view of an intermediate stage of a process for forming a package structure, in accordance with some embodiments.

FIG. 6 is a cross-sectional view of an intermediate stage of a process for forming a package structure, in accordance with some embodiments.

FIG. 7 is a cross-sectional view of an intermediate stage of a process for forming a package structure, in accordance with some embodiments.

FIG. 8 is a cross-sectional view of an intermediate stage of a process for forming a package structure, in accordance with some embodiments.

FIG. 9 is a cross-sectional view of an intermediate stage of a process for forming a package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Embodiments of the disclosure may relate to package structures such as three-dimensional (3D) packaging, 3D-IC devices, and 2.5D packaging. Embodiments of the disclosure form a package structure including a substrate that carries one or more dies or packages and a protective element (such as a protective lid) aside the dies or packages. The protective element may also function as a warpage-control element and/or heat dissipation element.

Other features and processes may also be included. For example, testing structures may be included to aid in the verification testing of the 3D packaging, 3DIC devices, and/or 2.5 D packaging. The testing structures may include, for example, test pads formed in a redistribution layer or on a substrate that allows testing to be conducted using probes or probe cards and the like. Verification testing may be performed on intermediate structures as well as the final structure. Additionally, the structures and methods disclosed herein may be used in conjunction with testing methodologies that incorporate intermediate verification of known good dies to increase the yield and decrease costs.

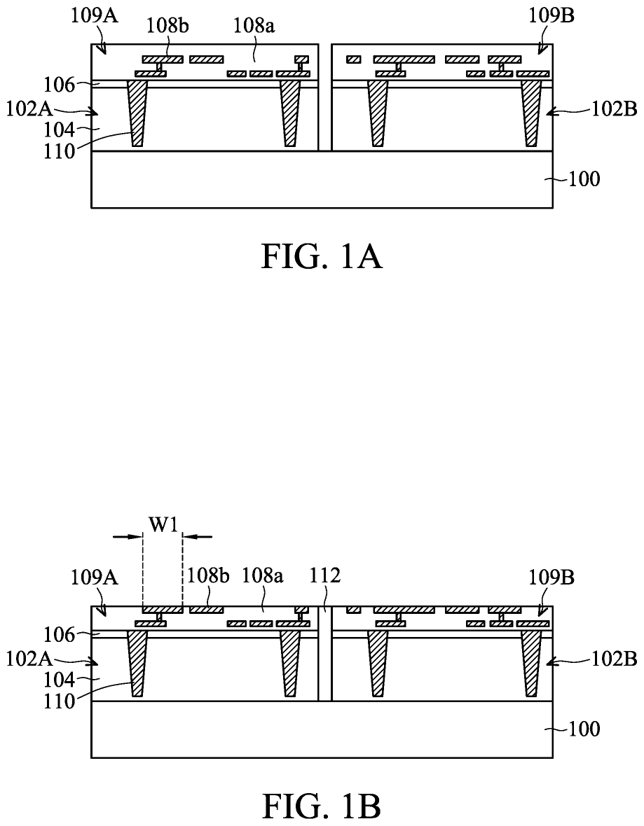

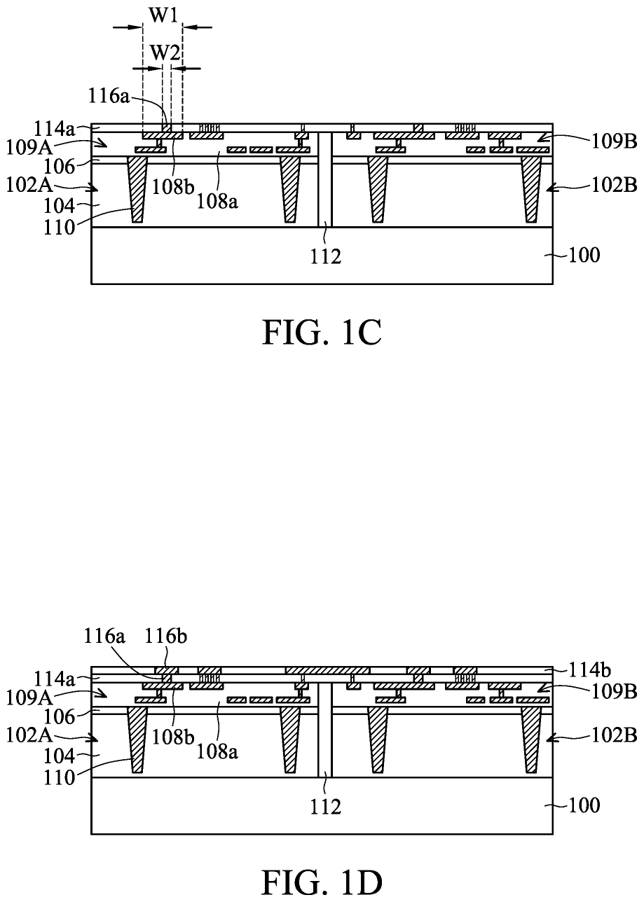

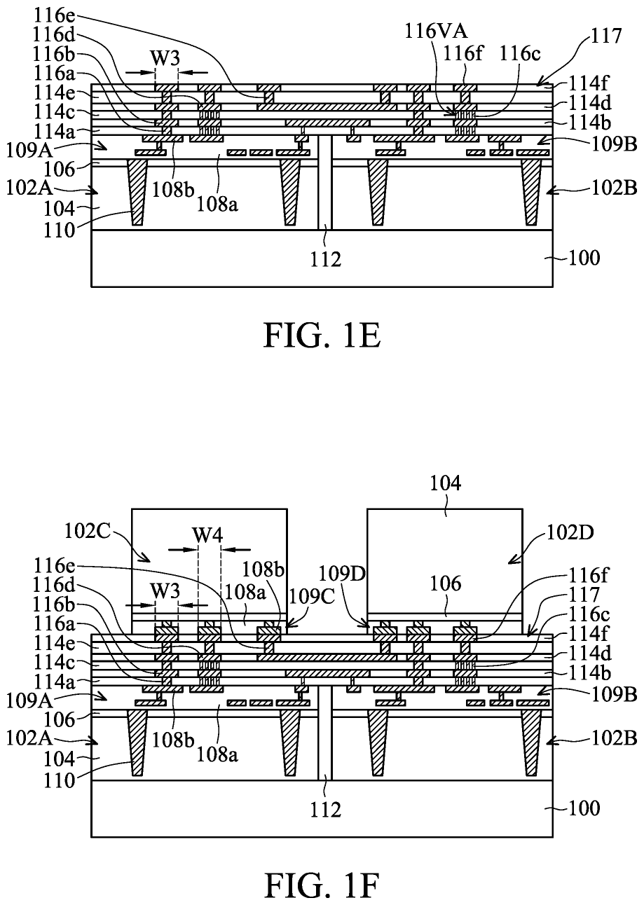

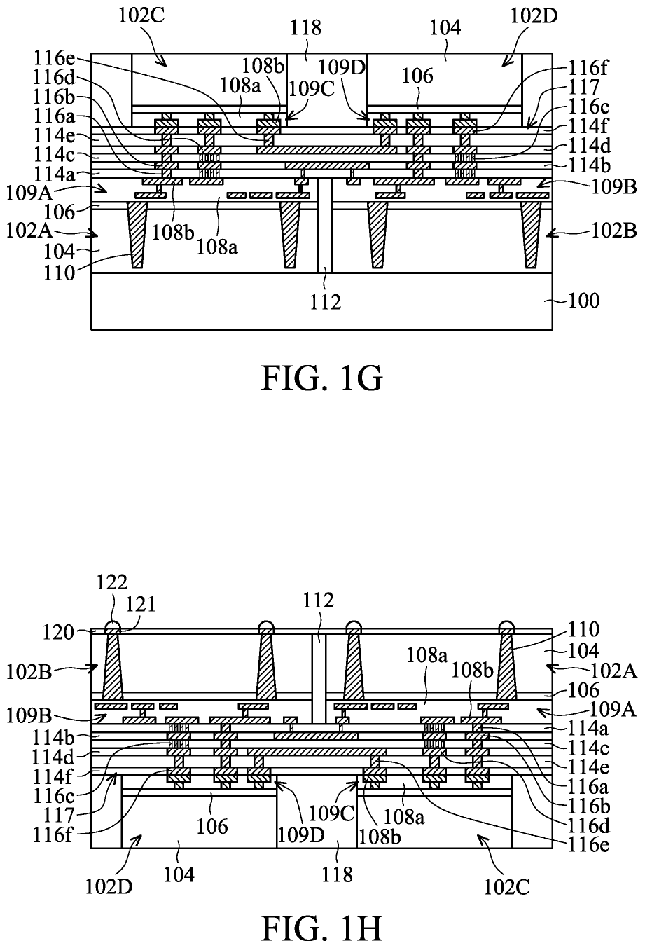

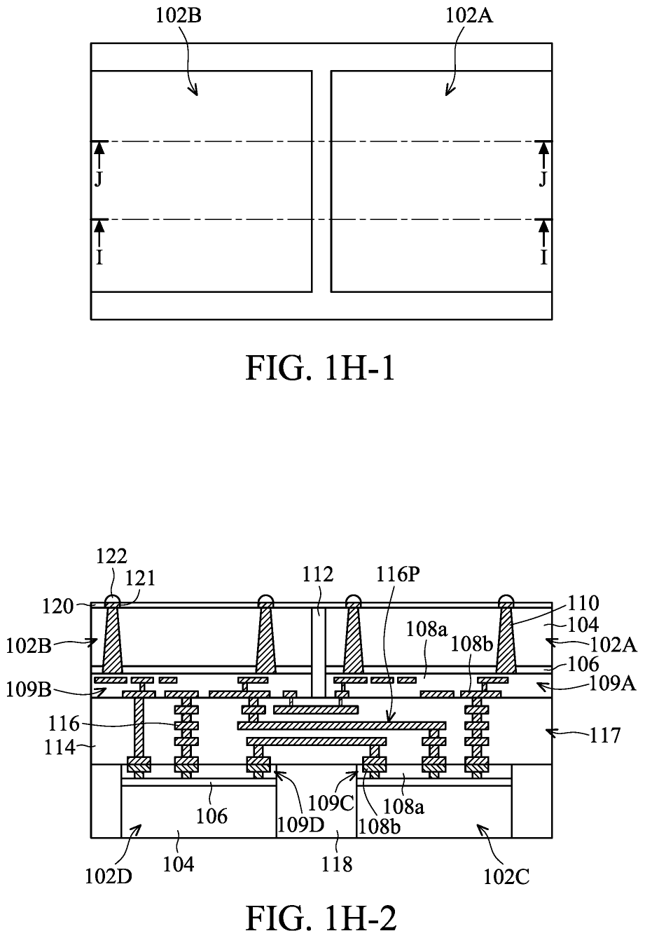

FIGS. 1A-1H are cross-sectional views of various stages of a process for forming a package structure, in accordance with some embodiments. As shown in FIG. 1A, multiple chip structures (including a chip structure 102A and a chip structure 102B) are disposed over a carrier substrate 100, in accordance with some embodiments. The carrier substrate 100 may be a carrier wafer. The carrier wafer may include a semiconductor wafer (such as a silicon wafer), a dielectric wafer (such as a glass wafer), or the like. In some embodiments, the carrier substrate 100 and the chip structures disposed thereon together form a reconstructed wafer.

In some embodiments, each of the chip structures 102A and 102B includes a substrate portion 104 and a device portion 106. Various device elements are formed in the device portion 106. Examples of the various device elements include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), diodes, or other suitable elements. Various processes may be used to form the various device elements, including deposition, etching, implantation, photolithography, annealing, and/or other suitable processes.

The chip structures 102A and 102B further include front-side interconnection portions 109A and 109B, respectively. Each of the front-side interconnection portions 109A and 109B includes multiple dielectric layers 108a and multiple conductive features 108b. The conductive features 108b may include conductive contacts, conductive lines, and conductive vias.

The device elements in the device portion 106 of the chip structure 102A are interconnected by the front-side interconnection portions 109A to form integrated circuit devices, such as a logic device, a memory device (e.g., static random access memory, SRAM), a radio frequency (RF) device, an input/output (I/O) device, a system-on-chip (SoC) device, one or more other types of devices, or a combination thereof. Similarly, the device elements in the device portion 106 of the chip structure 102B are interconnected by the front-side interconnection portions 109B to form the integrated circuit devices.

In some embodiments, each of the chip structures 102A and 102B includes multiple through-chip vias 110, as shown in FIG. 1A. Each of the through-chip vias 110 may penetrate through the device portion 106 and extends into the substrate portion 104. Each of the through-chip vias 110 may be electrically connected to one or more of the conductive features 108b formed in the front-side interconnection portion 109A or 109B. In some embodiments, a dielectric layer is formed between the substrate 104 and the through-chip vias 110, so as to prevent short circuiting between the through-chip vias 110.

As shown in FIG. 1B, a dielectric layer 112 is then deposited over the carrier substrate 100, in accordance with some embodiments. The dielectric layer 112 may cover the chip structures 102A and 102B and overfill the gaps between the chip structures 102A and 102B. In some embodiments, the dielectric layer 112 is in direct contact with the chip structures 102A and 102B.

Afterwards, a planarization process is performed to remove upper portions of the dielectric layer 112 and the front-side interconnection portions 109A and 109B, in accordance with some embodiments. As a result, some of the conductive features 108b are exposed. One of the conductive features 108b has a width W1, as shown in FIG. 1B. In some embodiments, the topmost surfaces of the conductive features 108b, the topmost surface of the dielectric layers 108a, and the topmost surface of the dielectric layer 112 are substantially at the same height.

The dielectric layer 112 may be made of or include silicon oxide, carbon-containing silicon oxide, silicon oxynitride, silicon nitride, carbon-containing silicon oxynitride, carbon-containing silicon nitride, one or more other suitable materials, or a combination thereof. In some embodiments, the dielectric layer 112 is free of polymer material. The dielectric layer 112 may be deposited using a chemical vapor deposition (CVD) process, a physical vapor deposition (PVD) process, an atomic layer deposition (ALD) process, a flowable chemical vapor deposition (FCVD) process, one or more other applicable processes, or a combination thereof. The planarization process may include a chemical mechanical polishing (CMP) process, a grinding process, a dry polishing process, an etching process, one or more other applicable processes, or a combination thereof.

As shown in FIG. 1C, a dielectric layer 114a and multiple conductive features 116a are formed over the dielectric layer 112 and the chip structures 102A and 102B, in accordance with some embodiments. Each of the conductive features 116a is electrically connected to a corresponding one of the conductive features 108b formed in the chip structures 102A and 102B. In some embodiments, the conductive features 108b with the width W1 is electrically connected to the conductive features 116a with a width W2. In some embodiments, the width W1 is wider than the width W2. In some embodiments, there is no solder elements formed between the conductive features 116a and the conductive features 108b of the chip structures 102A and 102B.

In some embodiments, the formation of the dielectric layer 114a and the multiple conductive features 116a involves a single damascene process. The dielectric layer 114a is deposited over the dielectric layer 112 and the chip structures 102A and 102B. The dielectric layer 114a extends across opposite edges of the chip structures 102A and 102B, as shown in FIG. 1C. The dielectric layer 114a may be made of or include silicon oxide, carbon-containing silicon oxide, silicon oxynitride, carbon-containing silicon oxynitride, one or more other suitable materials, or a combination thereof. In some embodiments, the dielectric layer 114a is free of polymer material. The dielectric layer 114a may be deposited using a CVD process, an ALD process, one or more other applicable processes, or a combination thereof.

Afterwards, one or more photolithography processes and one or more etching processes are used to partially remove the dielectric layer 114a. As a result, multiple openings that are used to contain conductive features are formed in the dielectric layer 114a. Each of the openings partially exposes the top surface of the corresponding conductive feature 108b thereunder.

One or more conductive materials are then deposited over the dielectric layer 114a to overfill these openings. A planarization process is then used to remove the portions of the conductive materials outside of the openings. As a result, the remaining portions of the conductive materials form the conductive features 116a, as shown in FIG. 1C. In some embodiments, before the formation of the conductive materials, a barrier layer is deposited along the sidewalls of the opening. The barrier layer may be made of or include titanium nitride, tantalum nitride, one or more other suitable materials, or a combination thereof.

The conductive materials may be made of or include copper, aluminum, cobalt, tungsten, nickel, gold, platinum, one or more other suitable materials, or a combination thereof. The conductive materials may be deposited using a CVD process, an electroplating process, an electrochemical plating process, an ALD process, a PVD process, one or more other applicable processes, or a combination thereof. The planarization process may include a CMP process, a grinding process, a dry polishing process, an etching process, one or more other applicable processes, or a combination thereof.

As shown in FIG. 1D, a dielectric layer 114b and multiple conductive features 116b are formed, in accordance with some embodiments. The material and formation method of the dielectric layer 114b may be the same as or similar to those of the dielectric layer 114a. The material and formation method of the conductive features 116b may be the same as or similar to those of the conductive features 116a. The dielectric layer 114b extends across the opposite edges of the chip structures 102A and 102B, as shown in FIG. 1D. In some embodiments, one of the conductive features 116b extends across the opposite edges of the chip structures 102A and 102B, as shown in FIG. 1D. The conductive feature 116b overlaps a first portion of the chip structure 102A and overlaps a second portion of the chip structure 102B. The conductive feature 116b that extends across the opposite edges of the chip structures 102A and 102B may be used to form electrical connection between the chip structures 102A and 102B.

Many variations and/or modifications can be made to embodiments of the disclosure. In some other embodiments, the dielectric layers 114a and 114b are replaced with a single dielectric layer. The conductive features 116a and 116b are formed in the single dielectric layer using a dual damascene process.

As shown in FIG. 1E, dielectric layers 114c, 114d, 114e, and 114f and conductive features 116c, 116d, 116e, and 116f are formed, in accordance with some embodiments. The material and formation method of the dielectric layer 114c-114f may be the same as or similar to those of the dielectric layer 114a. The material and formation method of the conductive features 116c-116f may be the same as or similar to those of the conductive features 116a. The dielectric layers 114a-114f and the conductive features 116a-116f together form an interconnection structure 117, as shown in FIG. 1E.

As shown in FIG. 1E, some of the conductive features 116f function as bonding pads. One of the conductive features 116f has a width W3. In some embodiments, some of the conductive features 116a-116f together form a stacked conductive via array 116VA, as shown in FIG. 1E. In some embodiments, a planarization process is performed on the interconnection structure 117 to provide the interconnection structure 117 with a planar surface, which facilitates the following bonding process.

The interconnection structure 117 may help to achieve complicated horizontal and vertical interconnect, which significantly increases the bandwidth density such as the horizontal bandwidth density. The interconnection structure 117 may also provide fine bond pitch and line pitch for reducing power consumption and latency.

As shown in FIG. 1F, a chip structure 102C and a chip structure 102D are directly bonded to the interconnection structure 117 through direct bonding, in accordance with some embodiments. The direct bonding may be a hybrid bonding that includes metal-to-metal bonding and dielectric-to-dielectric bonding. In some embodiments, there is no solder elements formed between the interconnection structure 117 and the chip structures 102C and 102D.

In some embodiments, similar to the chip structures 102A and 102B, each of the chip structures 102C and 102D includes a substrate portion 104 and a device portion 106. Various device elements are formed in the device portion 106. Examples of the various device elements include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), diodes, or other suitable elements. Various processes may be used to form the various device elements, including deposition, etching, implantation, photolithography, annealing, and/or other suitable processes.

The chip structures 102C and 102D further include front-side interconnection portions 109C and 109D, respectively. Each of the front-side interconnection portions 109C and 109D includes multiple dielectric layers 108a and multiple conductive features 108b. The conductive features 108b may include conductive contacts, conductive lines, and conductive vias. Some of the conductive features 108b function as bonding pads. One of the conductive features 108b has a width W4, as shown in FIG. 1F. In some embodiments, the width W4 is substantially equal to the width W3. In some other embodiments, the width W4 is narrower than the width W3.

The device elements in the device portion 106 of the chip structure 102C are interconnected by the front-side interconnection portions 109C to form the integrated circuit devices, such as a logic device, a memory device (e.g., static random access memory, SRAM), a radio frequency (RF) device, an input/output (I/O) device, a system-on-chip (SoC) device, one or more other types of devices, or a combination thereof. Similarly, the device elements in the device portion 106 of the chip structure 102D are interconnected by the front-side interconnection portions 109D to form the integrated circuit devices.

In some embodiments, the chip structures 102C and 102D are placed directly on the interconnection structure 117. As a result, the dielectric layers 108a of the chip structures 102C and 102D are in direct contact with the dielectric layer 114f of the interconnection structure 117. The conductive features 108b of the chip structures 102C and 102D are in direct contact with the conductive features 116f of the interconnection structure 117.

Before the placing of the chip structures 102C and 102D, planarization processes are performed on the interconnection structure 117 and the chip structures 102C and 102D, so as to provide highly planarized bonding surfaces of the chip structures 102C and 102D and the interconnection structure 117. In some embodiments, there is no gap between the dielectric layers 114f and 108a. In some embodiments, there is no gap between the conductive features 116f and 108b. In some embodiments, a thermal operation is then used to enhance the bonding between the conductive features 116f and 108b. The temperature of the thermal operation may within a range from about 100 degrees C. to about 700 degrees C.

As shown in FIG. 1G, a dielectric layer 118 is deposited over the interconnection structure 117, in accordance with some embodiments. The dielectric layer 118 may cover the chip structures 102C and 102D and overfill the gaps between the chip structures 102C and 102D. In some embodiments, the dielectric layer 118 is in direct contact with the interconnection structure 117 and the chip structures 102C and 102D.

Afterwards, a planarization process is performed to remove upper portions of the dielectric layer 118, in accordance with some embodiments. In some embodiments, the topmost surface of the dielectric layer 118 and the surfaces of the chip structures 102C and 102D are substantially at the same height. In some embodiments, the chip structures 102C and 102D are also partially removed during the planarization process.

The dielectric layer 118 may be made of or include silicon oxide, carbon-containing silicon oxide, silicon oxynitride, silicon nitride, carbon-containing silicon oxynitride, carbon-containing silicon nitride, one or more other suitable materials, or a combination thereof. In some embodiments, the dielectric layer 118 is free of polymer material. The dielectric layer 118 may be deposited using a chemical vapor deposition (CVD) process, a physical vapor deposition (PVD) process, an atomic layer deposition (ALD) process, a flowable chemical vapor deposition (FCVD) process, one or more other applicable processes, or a combination thereof. The planarization process may include a chemical mechanical polishing (CMP) process, a grinding process, a dry polishing process, an etching process, one or more other applicable processes, or a combination thereof.

Afterwards, the structure shown in FIG. 1G is flipped upside down, and the carrier substrate 100 is removed, in accordance with some embodiments. The chip structures 102A and 102B and the dielectric layer 112 are thinned. As a result, the through-chip vias 110 that are originally covered by the substrate portions 104 are exposed. Afterwards, a protective layer 120, under bump metallization (UBM) structures 121, and conductive bumps 122 are formed, as shown in FIG. 1H in accordance with some embodiments. The conductive bumps 122 may include a solder material. The solder material may be a tin-containing material. The tin-containing material may further include copper, silver, gold, aluminum, lead, one or more other suitable materials, or a combination thereof. In some other embodiments, the solder material is lead-free.

In some embodiments, a dicing process is used to separate the structure into multiple package structures. One of the package structures is shown in FIG. 1H. The package structure may function as a system on integrated chips (SoIC) that may further be integrated into a chip on wafer on substrate (CoWoS) package structure, an integrated fan-out (InFO) package structure, or the like.

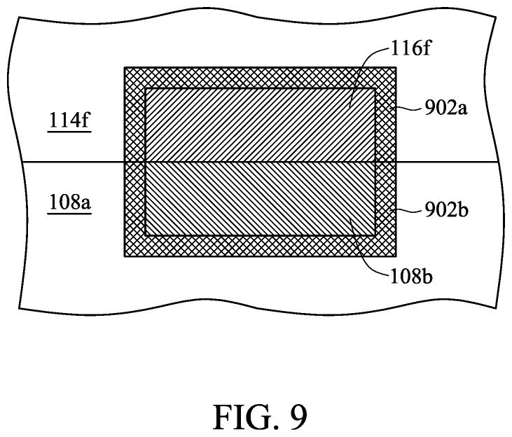

FIG. 9 is a cross-sectional view of an intermediate stage of a process for forming a package structure, in accordance with some embodiments. In some embodiments, FIG. 9 is an enlarged cross-sectional view partially showing the structure in FIG. 1H. In some embodiments, a barrier layer 902a is formed between the dielectric layer 114f and the conductive feature 116f, and a barrier layer 902b is formed between the dielectric layer 108a and the conductive feature 108b. In some embodiments, the dielectric layer 114f is in direct contact with the dielectric layer 108a, the conductive feature 116f is in direct contact with the conductive feature 108b, and the barrier layer 902a is in direct contact with the barrier layer 902b.

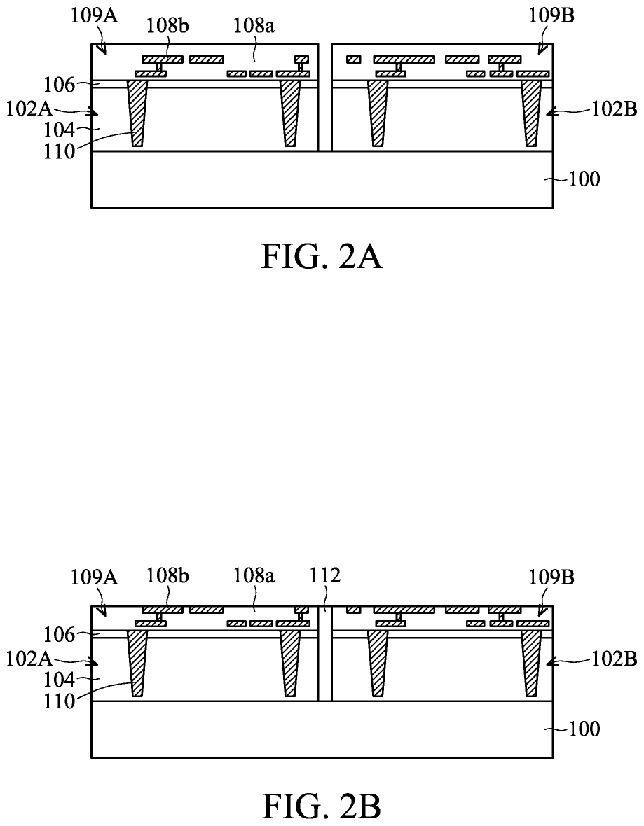

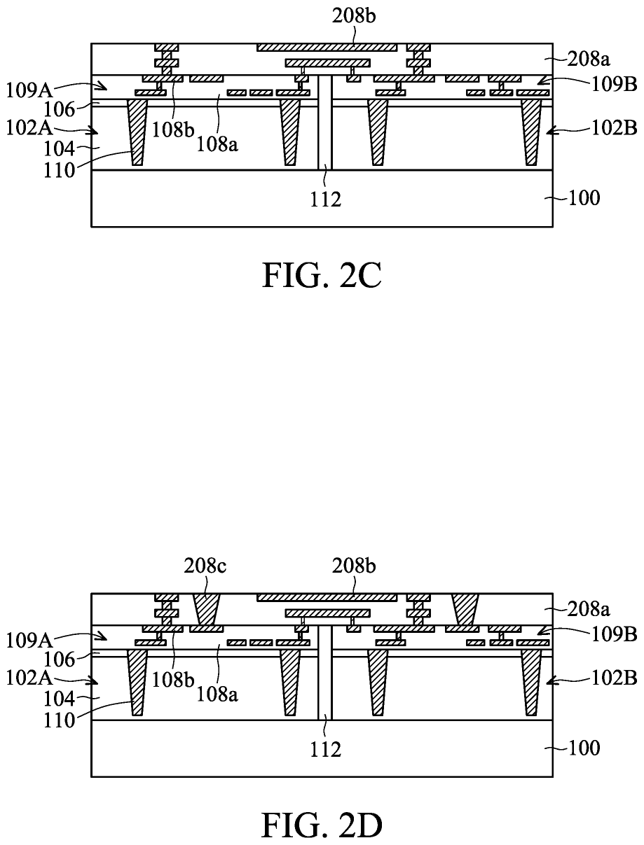

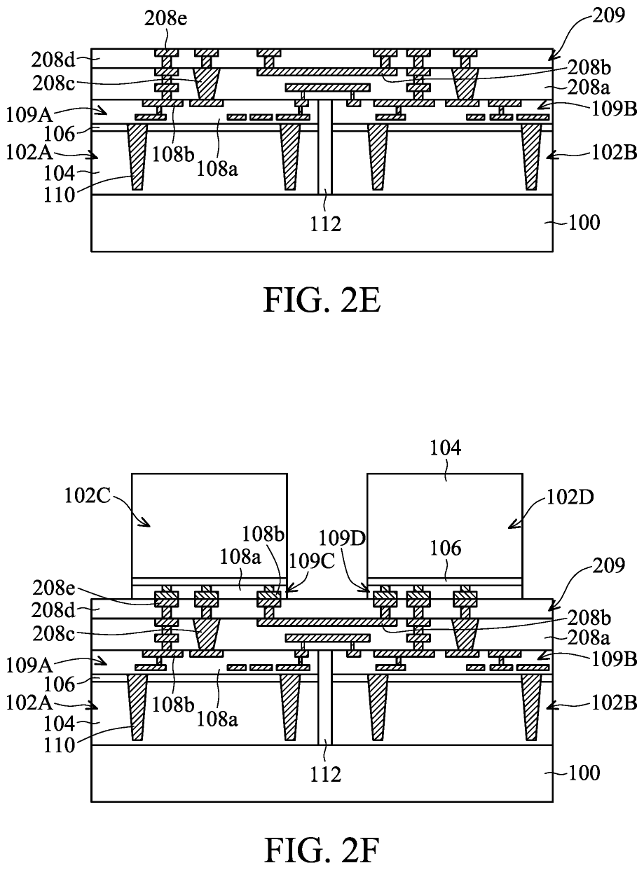

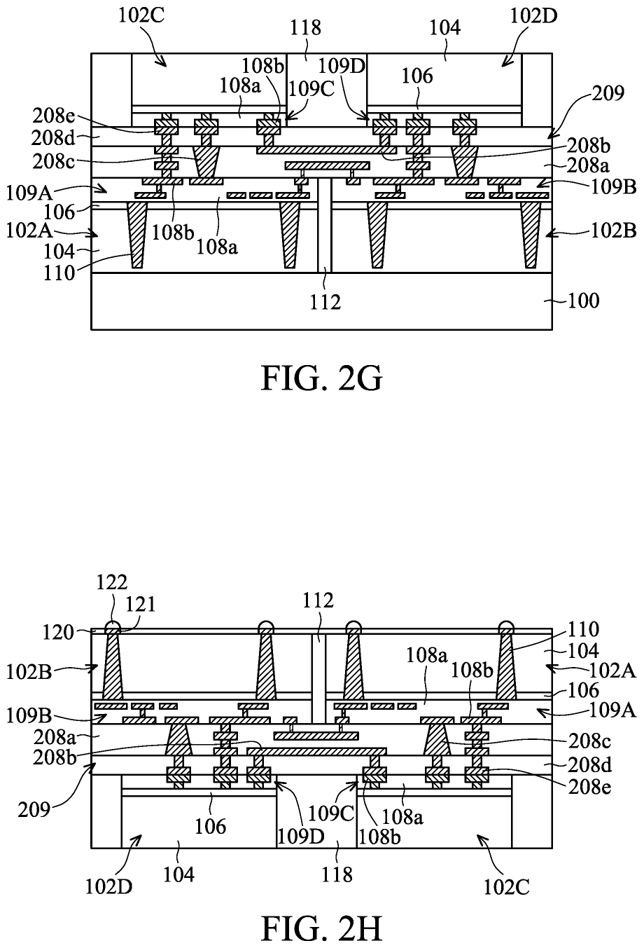

FIG. 1H-1 is a top view of an intermediate stage of a process for forming a package structure, in accordance with some embodiments. In some embodiments, FIG. 1H is a cross-sectional view of the structure taken along the line I-I in FIG. 1H-1. FIG. 1H-2 is a cross-sectional view of an intermediate stage of a process for forming a package structure, in accordance with some embodiments. In some embodiments, FIG. 1H-2 is a cross-sectional view of the structure taken along the line J-J in FIG. 1H-1. In some embodiments, a conductive feature 116P of the interconnection structure 117 extends across the opposite edges of the chip structures 102A and 102B, as shown in FIG. 1H-2. The conductive feature 116P also extends across the opposite edges of the chip structures 102C and 102D. The conductive feature 116P partially overlaps the chip structures 102A, 102B, 102C, and 102D. In some embodiments, the conductive path that includes the conductive feature 116P forms electrical connection between the chip structures 102B and 102C, as shown in FIG. 1H-2.

Many variations and/or modifications can be made to embodiments of the disclosure. In some embodiments, the interconnection structure includes a conductive via that penetrates through multiple dielectric layers. The through-dielectric via may help to enhance the power integrity. FIGS. 2A-2H are cross-sectional views of various stages of a process for forming a package structure, in accordance with some embodiments.

As shown in FIG. 2A, similar to the embodiments illustrated in FIG. 1A, chip structures 102A and 102B are disposed over a carrier substrate 100, in accordance with some embodiments. Afterwards, similar to the embodiments illustrated in FIG. 1B, a dielectric layer 112 is formed to laterally surround the chip structures 102A and 102B, as shown in FIG. 2B in accordance with some embodiments. A planarization process is used to thin the dielectric layer 112 and the chip structures 102A and 102B. As a result, the top surfaces of the dielectric layer 112, the conductive features 108b, and the dielectric layers 108a are substantially level.

As shown in FIG. 2C, multiple dielectric layers 208a and multiple conductive features 208b are formed over the chip structures 102A and 102B and the dielectric layer 112, in accordance with some embodiments. In some embodiments, the bottommost dielectric layer of the dielectric layers 208a is in direct contact with the front-side interconnection portions 109A and 109B and the dielectric layer 112. The material and formation method of the dielectric layers 208a may be the same as or similar to those of the dielectric layers 114a-114f. The material and formation method of the conductive features 208b may be the same as or similar to those of the conductive features 116a-116f.

As shown in FIG. 2D, through-dielectric vias 208c are formed in the dielectric layers 208a, in accordance with some embodiments. In some embodiments, each of the through-dielectric vias 208c penetrates through the dielectric layer 208a and is electrically connected to one of the conductive features 108b of the chip structure 102A or 102B. In some embodiments, the through-dielectric vias 208c include single via type, as shown in FIG. 2D. In some other embodiments, each of the through-dielectric vias 208c includes via array type. Two or more through-dielectric vias are arranged nearby and electrically connected to one of the conductive features 108b of the chip structure 102A or 102B.

Some of the conductive features 208b may together form a stacked via structure. In some embodiments, the through-dielectric via 208c has a larger radius than that of the stacked via structure. The through-dielectric via 208c with the larger radius may have improve the electrical performance (i.g., better power supply).

In some embodiments, one or more photolithography processes and one or more etching processes are used to partially remove the dielectric layers 208a. As a result, openings that penetrate through the dielectric layers 208a and expose some of the conductive features 108b of the chip structure 102A and/or 102B are formed.

Afterwards, one or more conductive materials are deposited to overfill these openings. The conductive materials may be made of or include copper, aluminum, cobalt, tungsten, nickel, gold, platinum, one or more other suitable materials, or a combination thereof. The conductive materials may be deposited using a CVD process, an electroplating process, an electrochemical plating process, an ALD process, a PVD process, one or more other applicable processes, or a combination thereof.

Afterwards, a planarization process may be used to remove the portions of the conductive materials outside of the openings. As a result, the remaining portions of the conductive materials form the through-dielectric vias 208c. The planarization process may include a CMP process, a grinding process, a dry polishing process, an etching process, one or more other applicable processes, or a combination thereof.

As shown in FIG. 2E, one or more dielectric layers 208d and conductive features 208e are formed, in accordance with some embodiments. The material and formation method of the dielectric layers 208d may be the same as or similar to those of the dielectric layer 114f. The material and formation method of conductive features 208e may be the same as or similar to those of the conductive features 116f. The dielectric layers 208a and 208d and the conductive features 208b, 208c, and 208e together form an interconnection structure 209, as shown in FIG. 2E. The interconnection structure 209 extends across opposite edges of the chip structures 102A and 102B. The interconnection structure 209 provides electrical path between the chip structures 102A and 102B.

In some embodiments, a planarization process (such as a CMP process) is used to ensure that the dielectric layers 208d and the conductive features 208e have planar surfaces, which facilitates the following bonding process. The topmost dielectric layer of the dielectric layers 208d and the topmost conductive features of the conductive features 208e may function as bonding structures.

As shown in FIG. 2F, similar to the embodiments illustrated in FIG. 1F, chip structures 102C and 102D are directly bonded to the interconnection structure 209, in accordance with some embodiments. Similar to the embodiments illustrated in FIG. 1F, a hybrid bonding that includes metal-to-metal bonding and dielectric-to-dielectric bonding is used the achieve the bonding between the interconnection structure 209 and the chip structures 102C and 102D.

As shown in FIG. 2G, similar to the embodiments illustrated in FIG. 1G, a dielectric layer 118 that laterally surrounds the chip structures 102C and 102D are formed, in accordance with some embodiments. The material and formation method of the dielectric layer 118 may be the same as or similar to those of the dielectric layer 118 shown in FIG. 1G. In some embodiments, the dielectric layer 118 extends across the interface between the dielectric layer 112 and the chip structure 102A or 102B, as shown in FIG. 2G.

Afterwards, processes that are the same as or similar to those illustrated in FIG. 1H are performed, in accordance with some embodiments. As a result, the structure shown in FIG. 2H is formed. A dicing process may be used to obtain multiple package structures. The package structures may then be integrated into CoWoS package structures, InFO package structures, or the like.

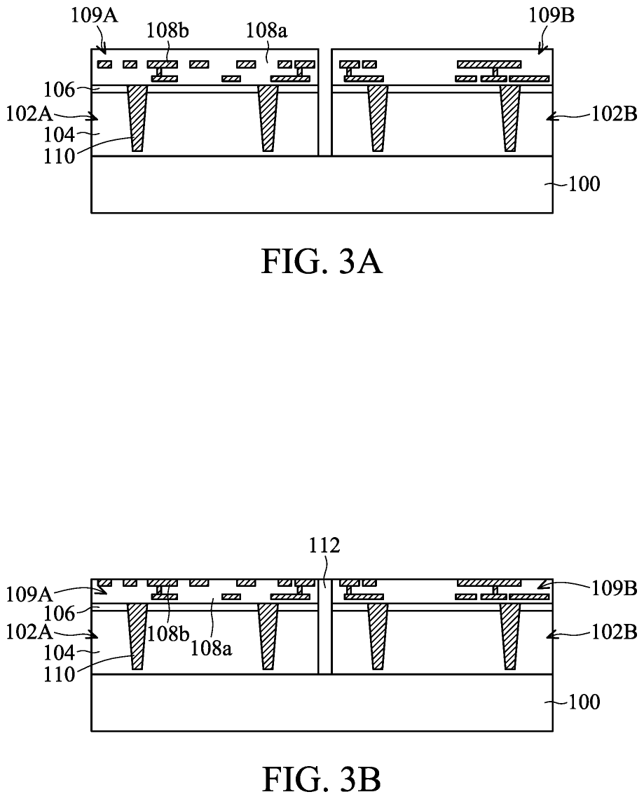

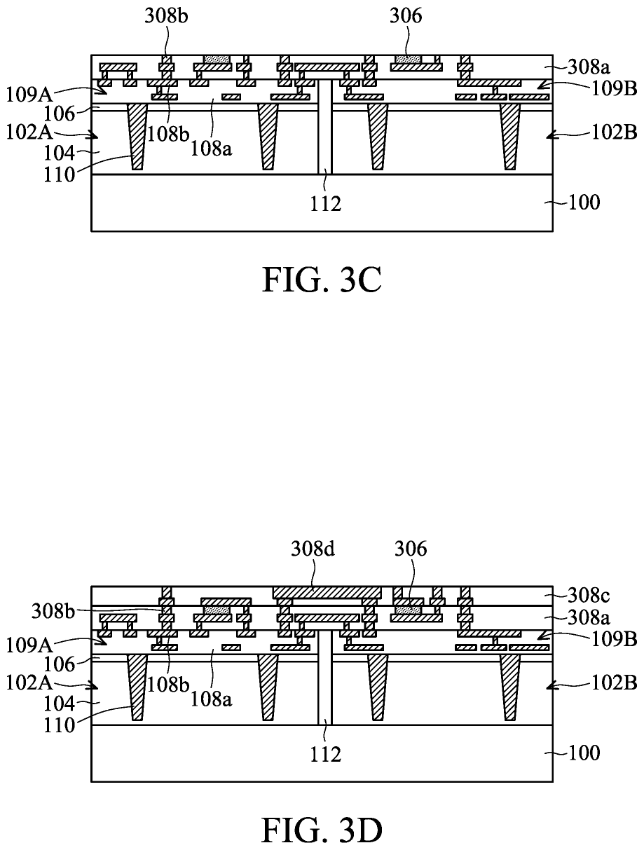

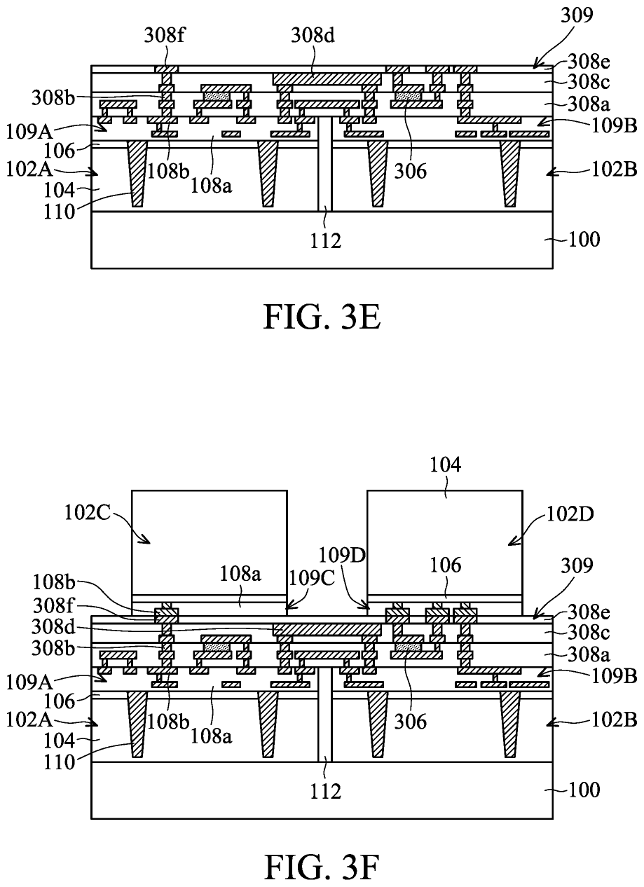

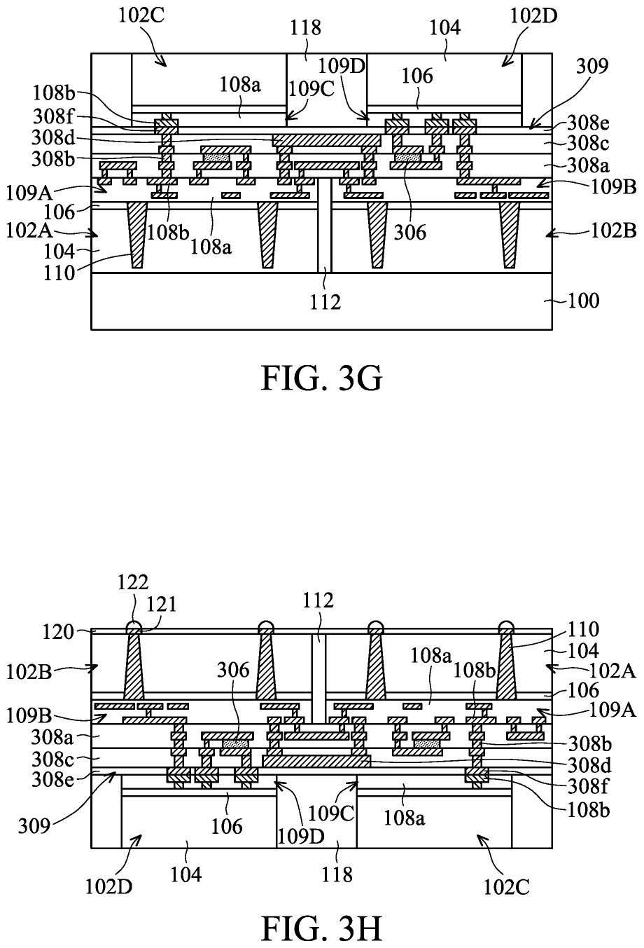

Many variations and/or modifications can be made to embodiments of the disclosure. In some embodiments, one or more passive devices (such as capacitors) are formed in the interconnection structure. FIGS. 3A-3H are cross-sectional views of various stages of a process for forming a package structure, in accordance with some embodiments.

As shown in FIG. 3A, similar to the embodiments illustrated in FIG. 1A, chip structures 102A and 102B are disposed over a carrier substrate 100, in accordance with some embodiments. Afterwards, similar to the embodiments illustrated in FIG. 1B, a dielectric layer 112 is formed to laterally surround the chip structures 102A and 102B, as shown in FIG. 3B in accordance with some embodiments. A planarization process is used to thin the dielectric layer 112 and the chip structures 102A and 102B. As a result, the top surfaces of the dielectric layer 112, the conductive features 108b, and the dielectric layers 108a are substantially level.

As shown in FIG. 3C, multiple dielectric layers 308a and multiple conductive features 308b are formed over the chip structures 102A and 102B and the dielectric layer 112, in accordance with some embodiments. The material and formation method of the dielectric layers 308a may be the same as or similar to those of the dielectric layers 114a-114f. The material and formation method of the conductive features 308b may be the same as or similar to those of the conductive features 116a-116f.

As shown in FIG. 3C, multiple capacitor dielectric structures 306 are formed over some of the conductive features 308b, in accordance with some embodiments. The capacitor dielectric structures 306 may be made of or include aluminum oxide, zirconium oxide, tantalum oxide, hafnium oxide, hafnium aluminum oxide, lanthanum oxide, titanium oxide, silicon nitride, one or more other suitable materials, or a combination thereof.

In some embodiments, one or more photolithography processes and one or more etching processes are used to partially remove the dielectric layers 308a. As a result, multiple openings that expose some of the conductive features 308b are formed. The conductive features 308b that are exposed by the openings may function as lower electrodes of the capacitors. Afterwards, one or more insulating layers are deposited to overfill the openings. The insulating layers may be deposited using a CVD process, an ALD process, one or more other applicable processes, or a combination thereof.

A planarization process is then performed to remove the portions of the insulating layers outside of the openings. As a result, the remaining portions of the insulating layers form the capacitor dielectric structures 306, as shown in FIG. 3C. The planarization process may include a CMP process, a grinding process, an etching process, one or more other applicable processes, or a combination thereof.

As shown in FIG. 3D, one or more dielectric layers 308c and conductive features 308d are formed, in accordance with some embodiments. The material and formation method of the dielectric layers 308c may be the same as or similar to those of the dielectric layers 308a. The material and formation method of conductive features 308d may be the same as or similar to those of the conductive features 308b. Some of the conductive features 308d are in contact with the capacitor dielectric structures 306 and function as upper electrodes of the capacitors.

As shown in FIG. 3E, a dielectric layer 308e and conductive features 308f are formed, in accordance with some embodiments. The material and formation method of the dielectric layer 308e may be the same as or similar to those of the dielectric layer 114f. The material and formation method of conductive features 308f may be the same as or similar to those of the conductive features 116f. The dielectric layers 308a, 308c, and 308e and the conductive features 308b, 308d, and 308f together form an interconnection structure 309, as shown in FIG. 3E. The interconnection structure 309 extends across opposite edges of the chip structures 102A and 102B. The interconnection structure 309 provides electrical path between the chip structures 102A and 102B.

In some embodiments, a planarization process (such as a CMP process) is used to ensure that the dielectric layers 308e and the conductive features 308f have planar surfaces, which facilitates the following bonding process. The dielectric layer 308e and the conductive features 308f may function as bonding structures.

As shown in FIG. 3F, similar to the embodiments illustrated in FIG. 1F, chip structures 102C and 102D are directly bonded to the interconnection structure 309, in accordance with some embodiments. In some embodiments, the chip structures 102C and 102D are directly bonded to the interconnection structure 309 through dielectric-to dielectric bonding and metal-to-metal bonding.

As shown in FIG. 3G, similar to the embodiments illustrated in FIG. 1G, a dielectric layer 118 that laterally surrounds the chip structures 102C and 102D are formed, in accordance with some embodiments. The material and formation method of the dielectric layer 118 may be the same as or similar to those of the dielectric layer 118 shown in FIG. 1G. In some embodiments, the dielectric layer 118 extends across the interface between the dielectric layer 112 and the chip structure 102A or 102B, as shown in FIG. 3G.

Afterwards, processes that are the same as or similar to those illustrated in FIG. 1H are performed, in accordance with some embodiments. As a result, the structure shown in FIG. 3H is formed. A dicing process may be used to obtain multiple package structures. The package structures may then be integrated into CoWoS package structures, InFO package structures, or the like.

In some embodiments, the chip structures 102A-102D are arranged in a face-to-face manner, as shown in FIG. 1H. For example, the device portion 106 of the chip structure 102A is between the substrate portion 104 of the chip structure 102A and the interconnection structure 117. The device portion 106 of the chip structure 102C is between the substrate portion 104 of the chip structure 102C and the interconnection structure 117. The front-side interconnection portions 109A and 109C both face the interconnection structure 117. However, embodiments of the disclosure are not limited thereto. Many variations and/or modifications can be made to embodiments of the disclosure. In some other embodiments, the chip structures 102A-102D are arranged in a face-to-back manner.

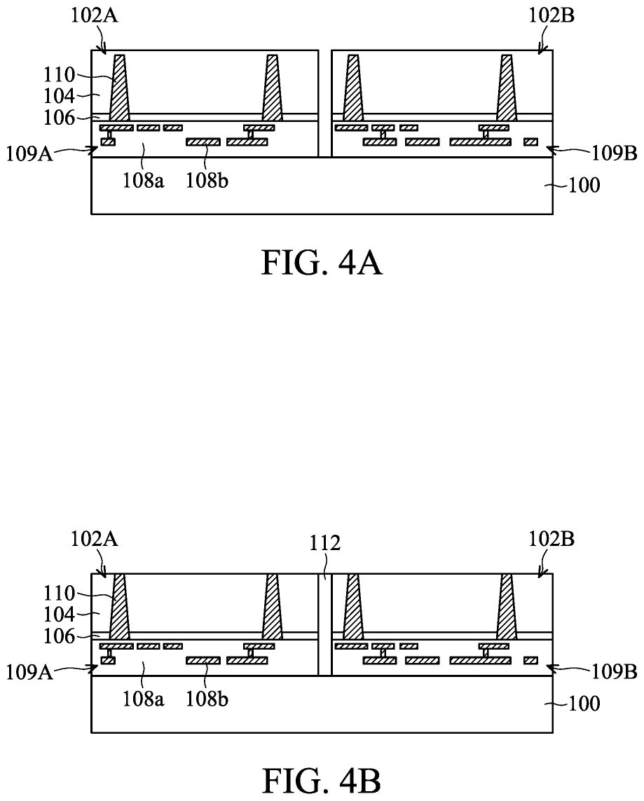

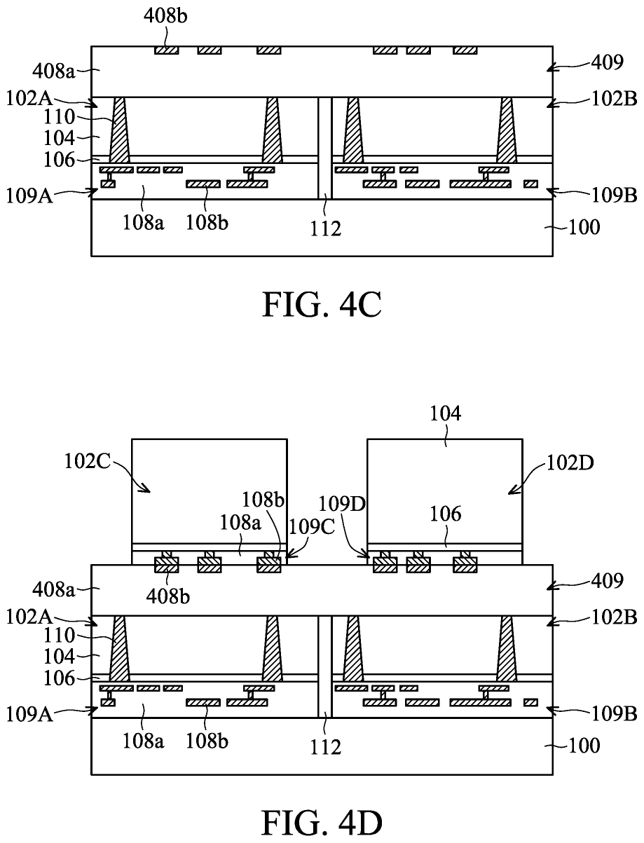

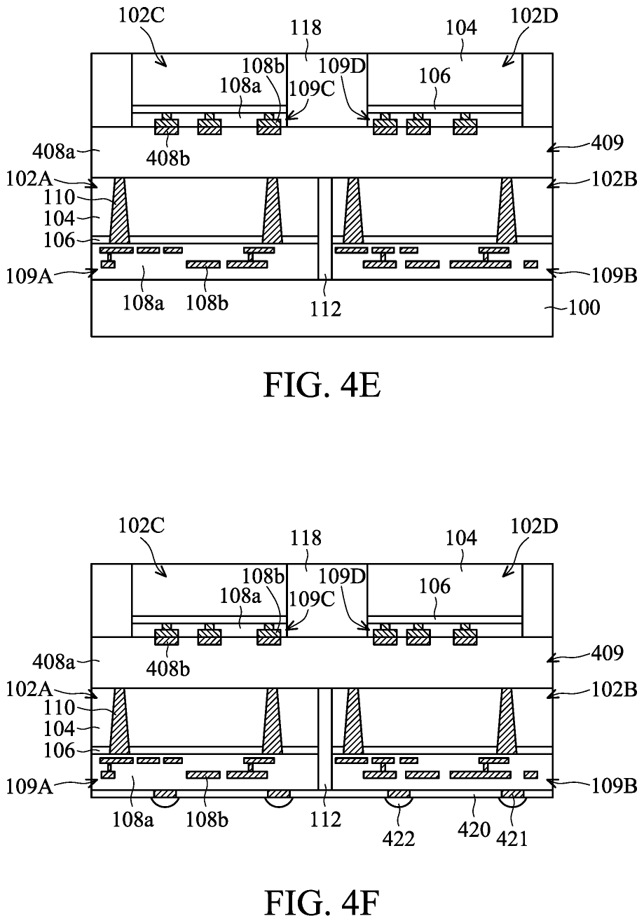

FIGS. 4A-4F are cross-sectional views of various stages of a process for forming a package structure, in accordance with some embodiments. As shown in FIG. 4A, similar to the embodiments illustrated in FIG. 1A, chip structures 102A and 102B are disposed over a carrier substrate 100, in accordance with some embodiments. As shown in FIG. 4A, the front-side interconnection portions 109A and 109B of the chip structures 102A and 102B face the carrier substrate 100 with the backsides of the chip structures 102A and 102B facing upwards.

Afterwards, similar to the embodiments illustrated in FIG. 1B, a dielectric layer 112 is formed to laterally surround the chip structures 102A and 102B, as shown in FIG. 4B in accordance with some embodiments. A planarization process is used to thin the dielectric layer 112 and the chip structures 102A and 102B. In some embodiments, the substrate portions 104 of the chip structures 102A and 102B are partially removed such that the through-chip vias 110 are exposed. As a result, the surfaces of the dielectric layer 112, the substrate portions 104, and the through-chip vias are substantially level.

As shown in FIG. 4C, multiple dielectric layers 408a and multiple conductive features 408b are formed over the chip structures 102A and 102B and the dielectric layer 112, in accordance with some embodiments. For clarity, only the topmost conductive features 408b that may function as bonding pads are shown in FIG. 4C. The material and formation method of the dielectric layers 408a may be the same as or similar to those of the dielectric layers 114a-114f. The material and formation method of the conductive features 408b may be the same as or similar to those of the conductive features 116a-116f. The dielectric layers 408a and the conductive features 408b together form an interconnection structure 409. In some embodiments, the interconnection structure 409 extends across the opposite edges of the chip structures 102A and 102B, as shown in FIG. 4C. In some embodiments, a planarization process (such as a CMP process) is used to ensure that the dielectric layers 408a and the conductive features 408b have planar surfaces, which facilitates the following bonding process.

As shown in FIG. 4D, similar to the embodiments illustrated in FIG. 1F, chip structures 102C and 102D are directly bonded to the interconnection structure 409, in accordance with some embodiments. Similar to the embodiments illustrated in FIG. 1F, a hybrid bonding that includes metal-to-metal bonding and dielectric-to-dielectric bonding is used the achieve the bonding between the interconnection structure 409 and the chip structures 102C and 102D.

As shown in FIG. 4E, similar to the embodiments illustrated in FIG. 1G, a dielectric layer 118 that laterally surrounds the chip structures 102C and 102D are formed, in accordance with some embodiments. The material and formation method of the dielectric layer 118 may be the same as or similar to those of the dielectric layer 118 shown in FIG. 1G. In some embodiments, the dielectric layer 118 extends across the interface between the dielectric layer 112 and the chip structure 102A or 102B, as shown in FIG. 4E.

As shown in FIG. 4F, the carrier substrate 100 is removed such that the front-side interconnection portions 109A and 109B of the chip structures 102A and 102B and the dielectric layer 112 are exposed, in accordance with some embodiments. Afterwards, a protective layer 420, under bump metallization (UBM) structures 421, and conductive bumps 422 are formed over the front-side interconnection portions 109A and 109B and the dielectric layer 112, as shown in FIG. 4F in accordance with some embodiments. A dicing process may then be used to obtain multiple package structures. The package structures may then be integrated into CoWoS package structures, InFO package structures, or the like.

In some embodiments, the chip structures 102A-102D are arranged in a face-to-back manner, as shown in FIG. 4F. For example, the substrate portion 104 of the chip structure 102A is between the device portion 106 of the chip structure 102A and the interconnection structure 409. The device portion 106 of the chip structure 102C is between the substrate portion 104 of the chip structure 102C and the interconnection structure 409. The front-side interconnection portions 109C face the interconnection structure 409, and the backside of the chip structure 102A faces the interconnection structure 409.

Many variations and/or modifications can be made to embodiments of the disclosure. In some embodiments, at least one of the chip structures 102A-102D includes multiple semiconductor dies that are bonded together.

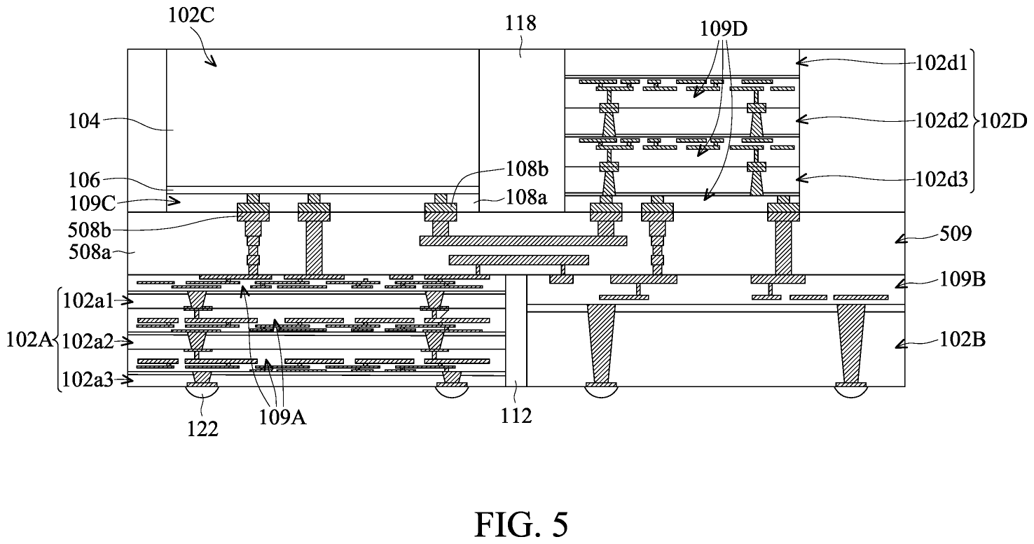

FIG. 5 is a cross-sectional view of an intermediate stage of a process for forming a package structure, in accordance with some embodiments. FIG. 5 shows a package structure that is similar to that shown in FIG. 1H. In some embodiments, each of the chip structures 102A and 102D includes multiple semiconductor dies (or chiplets) that are bonded together.

In some embodiments, the chip structure 102A includes semiconductor dies 102a1, 102a2, and 102a3 that are stacked chiplets. In some embodiments, the semiconductor dies 102a1 and 102a2 are bonded together in a back-to-face manner, as shown in FIG. 5. In some embodiments, the semiconductor dies 102a2 and 102a3 are also bonded together in a back-to-face manner.

In some embodiments, the chip structure 102D includes semiconductor dies 102d1, 102d2, and 102d3 that are stacked chiplets. In some embodiments, the semiconductor dies 102d1 and 102d2 are bonded together in a face-to-back manner, as shown in FIG. 5. In some embodiments, the semiconductor dies 102d2 and 102d3 are also bonded together in a face-to-back manner. In some embodiments, a dielectric layer (such as an oxide layer) is formed on the backsides of the semiconductor dies 102d2 and 102d3, so as to facilitate the bonding between the semiconductor dies 102d1 and 102d2 and the bonding between the semiconductor dies 102d2 and 102d3. These semiconductor dies may be bonded together using dielectric-to-dielectric bonding and metal-to-metal bonding.

In some embodiments, an interconnection structure 509 is formed over the chip structures 102A and 102B and the dielectric layer 112, as shown in FIG. 5. The interconnection structure 509 includes multiple dielectric layers 508a and multiple conductive features 508b. The material and formation method of the interconnection structure 509 may be the same as or similar to those of the interconnection structure 117 as illustrated in FIG. 1E.

In some embodiments, each of the interconnection structure 509 and the dielectric layer 112 is free of polymer material. In some embodiments, the interconnection structure 509 extends across the interface between the chip structure 102A and the dielectric layer 112, and the interconnection structure 509 also extends across the interface between the chip structure 102B and the dielectric layer 112.

In some embodiments, similar to the embodiments illustrated in FIG. 1F, the chip structures 102C and 102D are bonded to the interconnection structure 509 through dielectric-to-dielectric bonding and metal-to-metal bonding. The interconnection structure 509 provides multiple conductive paths between the chip structures 102A-102D.

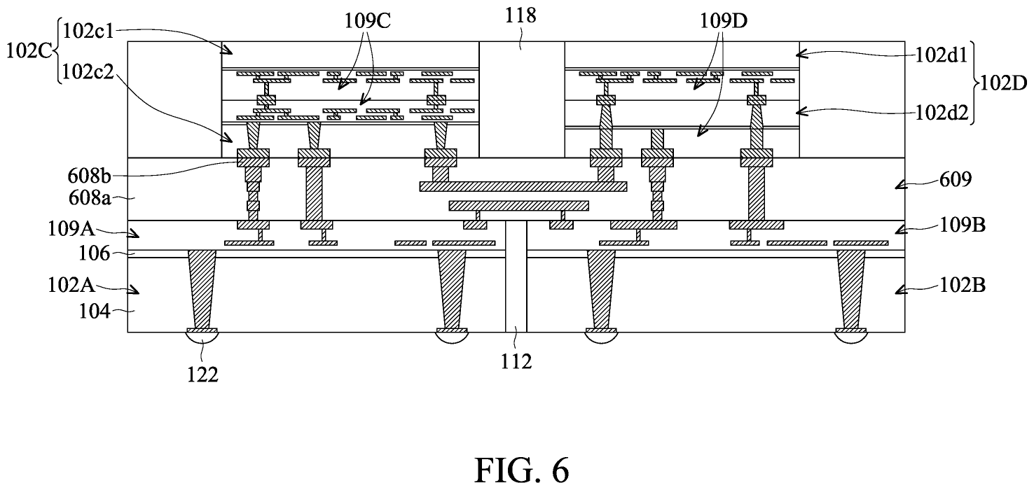

FIG. 6 is a cross-sectional view of an intermediate stage of a process for forming a package structure, in accordance with some embodiments. FIG. 6 shows a package structure that is similar to that shown in FIG. 5. In some embodiments, each of the chip structures 102C and 102D includes multiple semiconductor dies (or chiplets) that are bonded together.

In some embodiments, the chip structure 102C includes semiconductor dies 102c1 and 102c2 that are stacked chiplets. In some embodiments, the semiconductor dies 102c1 and 102c2 are bonded together in a face-to-face manner, as shown in FIG. 6. In some embodiments, the chip structure 102D includes semiconductor dies 102d1 and 102d2 that are stacked chiplets. In some embodiments, the semiconductor dies 102d1 and 102d2 are bonded together in a face-to-back manner, as shown in FIG. 6. In some embodiments, a dielectric layer (such as an oxide layer) is formed on the backsides of the semiconductor die 102d2, so as to facilitate the bonding between the semiconductor dies 102d1 and 102d2. These semiconductor dies may be bonded together through dielectric-to-dielectric bonding and metal-to-metal bonding.

In some embodiments, an interconnection structure 609 is formed over the chip structures 102A and 102B and the dielectric layer 112, as shown in FIG. 6. The interconnection structure 609 includes multiple dielectric layers 608a and multiple conductive features 608b. The material and formation method of the interconnection structure 609 may be the same as or similar to those of the interconnection structure 509 as illustrated in FIG. 5.

In some embodiments, each of the interconnection structure 609 and the dielectric layer 112 is free of polymer material. In some embodiments, the interconnection structure 609 extends across the interface between the chip structure 102A and the dielectric layer 112, and the interconnection structure 609 also extends across the interface between the chip structure 102B and the dielectric layer 112.

In some embodiments, similar to the embodiments illustrated in FIG. 1F, the chip structures 102C and 102D are bonded to the interconnection structure 609 through dielectric-to-dielectric bonding and metal-to-metal bonding. The interconnection structure 609 provides multiple conductive paths between the chip structures 102A-102D.

In some embodiments, the conductive bumps 122 are formed near the chip structures 102A and 102B, as shown in FIG. 6. However, embodiments of the disclosure are not limited thereto. Many variations and/or modifications can be made to embodiments of the disclosure. In some other embodiments, the conductive bumps are formed at the opposite side of the package structure.

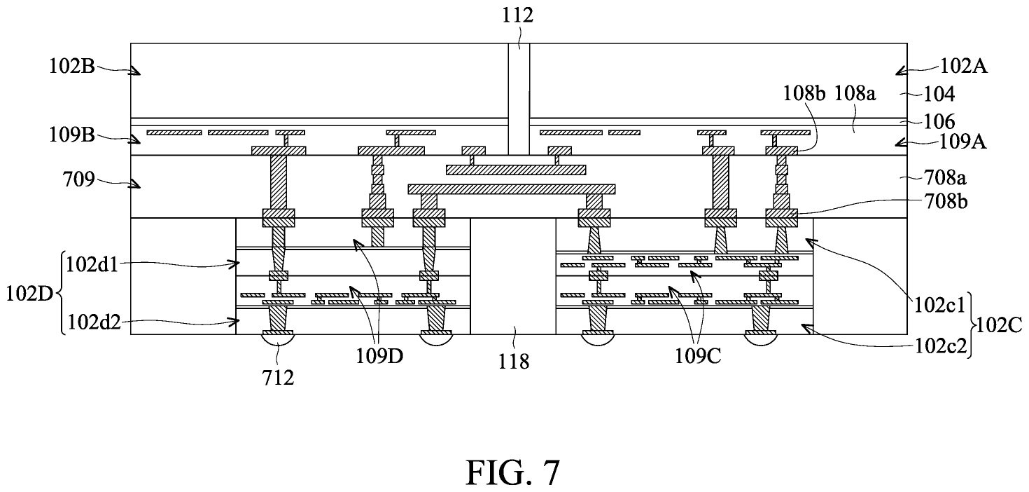

FIG. 7 is a cross-sectional view of an intermediate stage of a process for forming a package structure, in accordance with some embodiments. FIG. 7 shows a package structure that is similar to that shown in FIG. 6. In some embodiments, conductive bumps 712 are formed on the chip structures 102C and 102D.

In some embodiments, an interconnection structure 709 is formed over the chip structures 102A and 102B and the dielectric layer 112, as shown in FIG. 7. The interconnection structure 709 includes multiple dielectric layers 708a and multiple conductive features 708b. The material and formation method of the interconnection structure 709 may be the same as or similar to those of the interconnection structure 509 as illustrated in FIG. 5.

In some embodiments, each of the interconnection structure 709 and the dielectric layer 112 is free of polymer material. In some embodiments, the interconnection structure 709 extends across the interface between the chip structure 102A and the dielectric layer 112, and the interconnection structure 709 also extends across the interface between the chip structure 102B and the dielectric layer 112.

In some embodiments, similar to the embodiments illustrated in FIG. 1F, the chip structures 102C and 102D are bonded to the interconnection structure 709 through dielectric-to-dielectric bonding and metal-to-metal bonding. The interconnection structure 709 provides multiple conductive paths between the chip structures 102A-102D. The chip structure 102C is positioned between the interconnection structure 709 and some of the conductive bumps 712. Similarly, the chip structure 102D is positioned between the interconnection structure 709 and some of the conductive bumps 712.

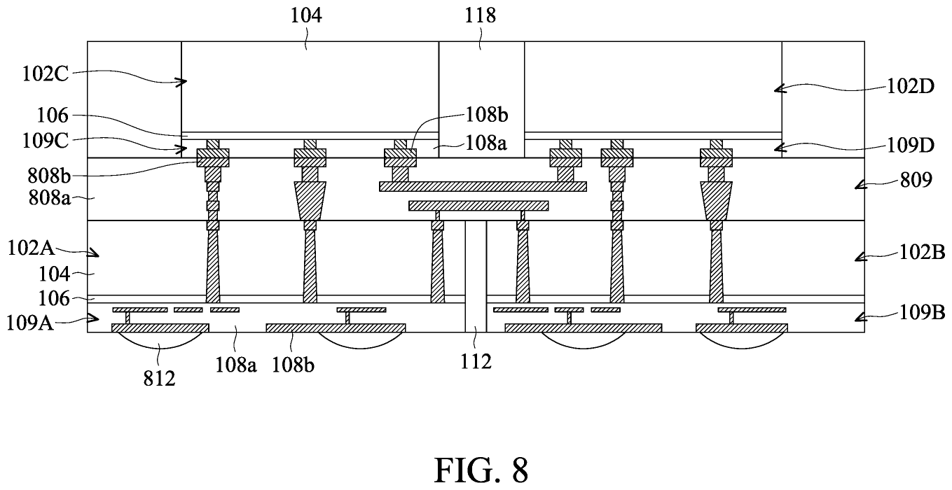

Many variations and/or modifications can be made to embodiments of the disclosure. FIG. 8 is a cross-sectional view of an intermediate stage of a process for forming a package structure, in accordance with some embodiments. FIG. 8 shows a package structure that is similar to that shown in FIG. 2. In some embodiments, the chip structures 102A-102D are arranged in a face-to-back manner.

In some embodiments, an interconnection structure 809 is formed over the backsides of the chip structures 102A and 102B and the dielectric layer 112, as shown in FIG. 8. The substrate portions 104 are between the interconnection structure 809 and the device portions 106. The interconnection structure 809 includes multiple dielectric layers 808a and multiple conductive features 808b. The material and formation method of the interconnection structure 809 may be the same as or similar to those of the interconnection structure 209 as illustrated in FIG. 2E.

In some embodiments, each of the interconnection structure 809 and the dielectric layer 112 is free of polymer material. In some embodiments, the interconnection structure 809 extends across the interface between the chip structure 102A and the dielectric layer 112, and the interconnection structure 809 also extends across the interface between the chip structure 102B and the dielectric layer 112.

In some embodiments, similar to the embodiments illustrated in FIG. 2F, the chip structures 102C and 102D are bonded to the interconnection structure 809 through dielectric-to-dielectric bonding and metal-to-metal bonding. The interconnection structure 809 provides multiple conductive paths between the chip structures 102A-102D. In some embodiments, conductive bumps 812 are then formed on the front-side interconnection portions 109A and 109B of the chip structures 102A and 102B, as shown in FIG. 8.

Embodiments of the disclosure form a package structure that includes a stack of multiple chip structures. An interconnection structure is formed over two or more chip structures. The interconnection structure extends across opposite edges of the chip structures. The interconnection structure includes multiple conductive features and multiple dielectric layers that are free of polymer material. One or more chip structures are directly bonded to the interconnection structure through dielectric-to-dielectric bonding and metal-to-metal bonding. The interconnection structure may thus provide electrical connection between the chip structures above and below the interconnection structure. The performance and reliability of the package structure are improved.

In accordance with some embodiments, a package structure is provided. The package structure includes a first chip structure and a second chip structure beside the first chip structure. The package structure also includes an interconnection structure over and contacting the first chip structure and the second chip structure. The interconnection structure has multiple dielectric layers and multiple conductive features. One of the conductive features extends across a first edge of the first chip structure and a second edge of the second chip structure and is electrically connecting the first chip structure and the second chip structure. The package structure further includes a third chip structure directly bonded to the interconnection structure through dielectric-to-dielectric bonding and metal-to-metal bonding.

In accordance with some embodiments, a method for forming a package structure is provided. The method includes disposing a first chip structure and a second chip structure over a carrier substrate. The method also includes forming an interconnection structure directly over and contacting the first chip structure and the second chip structure. The interconnection structure has multiple dielectric layers and multiple conductive features. One of the conductive features extends across a first edge of the first chip structure and a second edge of the second chip structure and is electrically connecting the first chip structure and the second chip structure. The method further includes directly bonding a third chip structure to the interconnection structure through dielectric-to-dielectric bonding and metal-to-metal bonding.

In accordance with some embodiments, a package structure is provided. The package structure includes a first chip structure and a second chip structure beside the first chip structure. The package structure also includes an interconnection structure over and contacting the first chip structure and the second chip structure. The interconnection structure has multiple silicon-containing oxide layers and multiple conductive features. One of the conductive features overlaps a first portion of the first chip structure and a second portion of the second chip structure and is electrically connecting the first chip structure and the second chip structure. The package structure further includes a third chip structure directly bonded to the interconnection structure. The interconnection structure extends across opposite edges of the third chip structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first chip structure;
a second chip structure beside the first chip structure;
an interconnection structure over and contacting the first chip structure and the second chip structure, wherein the interconnection structure has a plurality of dielectric layers and a plurality of conductive features, and one of the conductive features extends across a first edge of the first chip structure and a second edge of the second chip structure and is electrically connecting the first chip structure and the second chip structure; and
a third chip structure directly bonded to the interconnection structure through dielectric-to-dielectric bonding and metal-to-metal bonding.

2. The package structure as claimed in claim 1, further comprising:
a fourth chip structure directly bonded to the interconnection structure through dielectric-to-dielectric bonding and metal-to-metal bonding, wherein the interconnection structure extends across a third edge of the third chip structure and a fourth edge of the fourth chip structure.

3. The package structure as claimed in claim 1, further comprising:
a through-dielectric via penetrating at least some of the dielectric layers of the interconnection structure.

4. The package structure as claimed in claim 1, wherein the first chip structure has a substrate portion and a device portion, and the device portion is between the substrate portion and the interconnection structure.

5. The package structure as claimed in claim 1, wherein the first chip structure has a substrate portion and a device portion, and the substrate portion is between the device portion and the interconnection structure.

6. The package structure as claimed in claim 1, wherein the second chip structure is electrically connected to the third chip structure through a conductive path formed in the interconnection structure, and the conductive path extends across the first edge of the first chip structure, the second edge of the second chip structure, and a third edge of the third chip structure.

7. The package structure as claimed in claim 1, wherein at least one of the first chip structure, the second chip structure, and the third chip structure has a plurality of semiconductor dies that are bonded together.

8. The package structure as claimed in claim 1, further comprising:
a plurality of conductive bumps formed on the first chip structure and the second chip structure, wherein the interconnection structure is between the third chip structure and the conductive bumps.

9. The package structure as claimed in claim 1, further comprising:
a plurality of conductive bumps formed on the third chip structure, wherein the interconnection structure is between the first chip structure and the conductive bumps.

10. The package structure as claimed in claim 1, further comprising a plurality of through-chip vias formed in at least one of the first chip structure, the second chip structure, and the third chip structure.

11. A method for forming a package structure, comprising
disposing a first chip structure and a second chip structure over a carrier substrate;
forming an interconnection structure directly over and contacting the first chip structure and the second chip structure, wherein the interconnection structure has a plurality of dielectric layers and a plurality of conductive features, and one of the conductive features extends across a first edge of the first chip structure and a second edge of the second chip structure and is electrically connecting the first chip structure and the second chip structure; and
directly bonding a third chip structure to the interconnection structure through dielectric-to-dielectric bonding and metal-to-metal bonding.

12. The method for forming a package structure as claimed in claim 11, further comprising:
directly bonding a fourth chip structure to the interconnection structure through dielectric-to-dielectric bonding and metal-to-metal bonding, wherein the interconnection structure extends across a third edge of the third chip structure and a fourth edge of the fourth chip structure.

13. The method for forming a package structure as claimed in claim 12, further comprising:
forming a first dielectric structure over the carrier substrate to fill a gap between the first chip structure and the second chip structure; and
forming a second dielectric structure over the interconnection structure to surround the third chip structure and the fourth chip structure.

14. The method for forming a package structure as claimed in claim 11, further comprising:
forming a stacked conductive via array in the interconnection structure.

15. The method for forming a package structure as claimed in claim 11, further comprising:
forming a through-dielectric via penetrating through some of the dielectric layers of the interconnection structure.

16. The method for forming a package structure as claimed in claim 11, further comprising:
performing a chemical mechanical polishing process on the interconnection structure before directly bonding the third chip structure to the interconnection structure.

17. A package structure, comprising:
a first chip structure;
a second chip structure beside the first chip structure;
an interconnection structure over and contacting the first chip structure and the second chip structure, wherein the interconnection structure has a plurality of silicon-containing oxide layers and a plurality of conductive features, and at least one of the conductive features overlaps a first portion of the first chip structure and a second portion of the second chip structure and is electrically connecting the first chip structure and the second chip structure; and
a third chip structure directly bonded to the interconnection structure, wherein the interconnection structure extends across opposite edges of the third chip structure.

18. The chip structure as claimed in claim 17, wherein the interconnection structure is free of polymer material.

19. The chip structure as claimed in claim 17, further comprising:
a dielectric layer laterally surrounding the third chip structure, wherein the dielectric layer is in direct contact with the interconnection structure, and the dielectric layer is free of polymer material.

20. The chip structure as claimed in claim 17, further comprising:
a fourth chip structure directly bonded to the interconnection structure through dielectric-to-dielectric bonding and metal-to-metal bonding, wherein the second chip structure extends across opposite edges of the fourth chip structure.
